(19) United States
(12) Patent Application Publication
(10) Pub. No.: US 2004/0139601 A1
(43) Pub. Date: Jul. 22, 2004

(54) Method for cutting a wafer

(76) Inventor: Simon Shiau, Hsinchu Hsien (TW)

Correspondence Address: PRO-TECHTOR INTERNATIONAL, 20775 Norada Court, Saratoga, CA, 95070-3018, US

(21) Appl. No.: 10/346,765

(22) Filed: Jan. 16, 2003

(51) Int. Cl. H05K 3/30; B23P 17/00

(52) U.S. Cl. 29/832; 29/412; 29/417

(57) ABSTRACT

A method for cutting a wafer. The method includes the steps of: providing a first protection layer; providing a wafer, which comprises a top surface, a bottom surface mounted to the first protection layer, a plurality of semiconductor chips, and saw streets formed between adjacent semiconductor chips on the top surface of the wafer; providing a second protection layer to cover the top surface of the wafer so as to protect the top surface of the wafer; provide a cutter to cut the wafer into a plurality of individual semiconductor chips along the saw streets on the top surface of the wafer; and removing the first protection layer and second protection layer on each semiconductor chip. Thus, it is possible to prevent the waste chips generated during the cutting process from contaminating each semiconductor chip.

### BACKGROUND OF THE INVENTION

1. Field of the Invention

The invention relates to a method for cutting a wafer, and more particularly to a method in which two protection layers are provided at two faces of the wafer so that the waste chips, which are generated during the wafer cutting process, may not contaminate the semiconductor chip.

2. Description of the Related Art

As shown in FIG. 1, a conventional wafer 10 includes a plurality of semiconductor chips 12 formed thereon, and a plurality of saw streets 14 formed between adjacent semiconductor chips 12. Then, the wafer 10 may be cut into a plurality of individual semiconductor chips 12 along the saw streets 14.

In order to prevent the cut semiconductor chips 12 from scattering during the wafer cutting process, the wafer 10 is first fixed to the protection layer 16, and then a cutter is used to cut the wafer 10 into the semiconductor chips 12 along the saw streets 14. Next, the protection layer 16 is removed.

However, during the cutting process, the waste chips may contaminate the semiconductor chips 12. The semiconductor chips 12 have to be rinsed and then dried. Therefore, the manufacturing processes are complicated and the cost is high.

### SUMMARY OF THE INVENTION

An object of the invention is to provide a wafer cutting method capable of preventing the waste chips from contaminating the semiconductor chips during the cutting process so that the manufacturing cost may be lowered.

Another object of the invention is to provide a wafer cutting method capable of omitting the rinsing and drying processes after the wafer cutting process so that the manufacturing costs may be lowered.

To achieve the above-mentioned objects, the invention provides a method for cutting a wafer. The method includes the steps of: providing a first protection layer; providing a wafer, which comprises a top surface, a bottom surface mounted to the first protection layer, a plurality of semiconductor chips, and saw streets formed between adjacent semiconductor chips on the top surface of the wafer; providing a second protection layer to cover the top surface of the wafer so as to protect the top surface of the wafer; provide a cutter to cut the wafer into a plurality of individual semiconductor chips along the saw streets on the top surface of the wafer; and removing the first protection layer and second protection layer on each semiconductor chip.

Thus, it is possible to prevent the waste chips generated during the cutting process from contaminating each semiconductor chip.

### BRIEF DESCRIPTION OF THE DRAWINGS

FIG. 1 is a schematic illustration showing a conventional wafer after being cut.

FIG. 2 is a first schematic illustration showing a method for cutting a wafer of the invention.

FIG. 3 is a second schematic illustration showing the method for cutting the wafer of the invention.

FIG. 4 is a third schematic illustration showing the method for cutting the wafer of the invention.

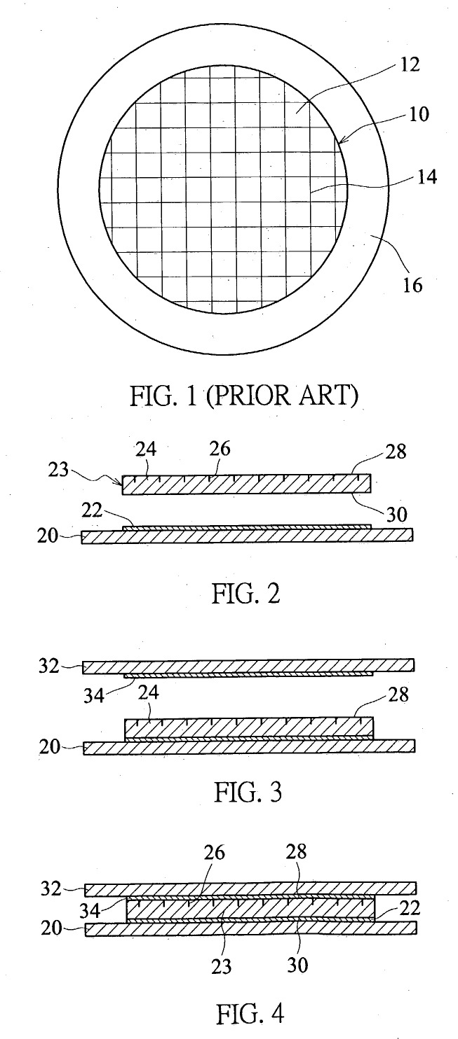

### DETAILED DESCRIPTION OF THE INVENTION

Referring to FIGS. 2 to 4, a method for cutting a wafer of the invention includes the following steps.

First, a first protection layer 20, which is a tape having a first adhesive layer 22 in this embodiment, is provided.

Then, a wafer 23, on which a plurality of semiconductor chips 24 is formed, is provided. The wafer 23 has a top surface 28 and a bottom surface 30, and the bottom surface 30 of the wafer 23 is placed on the first protection layer 20 and is adhered to the first protection layer 20 by the adhesive layer 22. Plural saw streets 26 are formed between adjacent semiconductor chips 24 on the top surface 28 of the wafer 23 in advance.

Next, a second protection layer 32, which is a tape having a second adhesive layer 34 in this embodiment, is provided. The second protection layer 32 is adhered to the top surface 28 of the wafer 23 by the second adhesive layer 34 to protect each semiconductor chip 24.

Then, a cutter is provided to cut the wafer 23 into a plurality of individual semiconductor chips 24 along the saw streets 26 on the top surface 28 of the wafer 23.

Next, the first protection layer 20 and the second protection layer 32 on each semiconductor chip 24 are removed, and the cutting process of the wafer 23 is finished.

Because the top surface 28 of the wafer 23 is covered and protected by the second protection layer 32, the waste chips generated during the cutting process cannot contaminate the semiconductor chips 24. Therefore, the semiconductor chips 24 need not to be rinsed and dried, the manufacturing processes are simplified, and the cost may be lowered.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. A method for cutting a wafer, comprising the steps of:
providing a first protection layer;
providing a wafer, which comprises a top surface, a bottom surface mounted to the first protection layer, a plurality of semiconductor chips, and saw streets formed between adjacent semiconductor chips on the top surface of the wafer;
providing a second protection layer to cover the top surface of the wafer so as to protect the top surface of the wafer;
provide a cutter to cut the wafer into a plurality of individual semiconductor chips along the saw streets on the top surface of the wafer; and
removing the first protection layer and second protection layer on each semiconductor chip.

2. The method according to claim 1, wherein the first protection layer is a tape having a first adhesive layer adhered to the bottom surface of the wafer.

3. The method according to claim 1, wherein the second protection layer is a tape having a second adhesive layer adhered to the top surface of the wafer.
